(19) United States
(12) Patent Application Publication
(10) Pub. No.: US 2023/0080501 A1
(43) Pub. Date: Mar. 16, 2023

(54) LASER PROCESSING DEVICE

(71) Applicant: Panasonic Intellectual Property Management Co., Ltd., Osaka (JP)

(72) Inventors: TOMOYUKI KAGEYAMA, Osaka (JP); HITOSHI NAGANO, Osaka (JP); SHINICHI ARITA, Osaka (JP)

(21) Appl. No.: 18/051,868

(22) Filed: Nov. 1, 2022

Related U.S. Application Data
(63) Continuation of application No. PCT/JP2021/018711, filed on May 18, 2021.

(30) Foreign Application Priority Data
May 28, 2020 (JP) 2020-093507

(51) Int. Cl. B23K 26/70; B23K 26/06; H01S 5/024; H01S 5/02315

(52) U.S. Cl. CPC B23K 26/703; B23K 26/0643; B23K 26/0648; H01S 5/02423; H01S 5/02315

(57) ABSTRACT

Laser processing device (100) includes laser oscillator (10) that generates laser light beam (LB), optical fiber (30) that transmits laser light beam (LB), laser head (40) that emits laser light beam (LB) to workpiece (W), and chiller (50) that passes and circulates cooling water through laser oscillator (10) to cool laser oscillator (10). Laser oscillator (10) includes: a plurality of laser diodes; and a base having a cooling water channel therein and having the laser diodes mounted on a surface thereof. Laser processing device (100) is configured to change the incident angle of laser light beam (LB) entering optical fiber (30) by changing the water pressure of the cooling water flowing through the cooling water channel.

This application is a continuation application of the PCT International Application No. PCT/JP2021/018711 filed on May 18, 2021, which claim the benefit of foreign priority of Japanese patent application No. 2020-093507 filed on May 28, 2020, the contents all of which are incorporated herein by reference.

### TECHNICAL FIELD

The present disclosure relates to a laser processing device.

### BACKGROUND ART

Conventionally, a laser processing device that transmits a high-output laser light beam through an optical fiber and irradiates a workpiece with the laser light beam has been widely known. Consider a case where the optical fiber has a so-called double core structure in which a first core is provided at the center of the axis and a second core is provided with a first cladding interposed between the first core and the second core, the first cladding being provided coaxially with the first core. In this case, the beam profile of the laser light beam radiated to the workpiece can be changed by changing the incident position of the laser light beam on an incident end surface of the optical fiber.

For example, PTL 1 discloses a configuration in which an inclination of a reflection mirror is changed by an actuator with respect to an optical fiber having a double core structure to change the incident position of a laser light beam on an incident end surface of the optical fiber. The beam quality of the laser light beam is improved by appropriately adjusting the incident position.

### CITATION LIST

### Patent Literature

PTL 1: Japanese Translation of PCT International Application Publication No. 2019-510276

### SUMMARY OF THE INVENTION

### Technical Problem

However, the conventional configuration disclosed in PTL 1 needs to separately provide the actuator and to provide a movable mechanism in the reflection mirror. In such a case, the configuration and control of the laser processing device become complicated, and the cost increases. In addition, in a case where a failure occurs in the movable mechanism provided in the reflection mirror, the replacement frequency of the reflection mirror may increase, by which the down time of the laser processing device may increase.

The present disclosure has been made in view of the above respect, and an object thereof is to provide a laser processing device capable of adjusting a beam profile of a laser light beam with a simple configuration by changing an incident position of the laser light beam on an incident end surface of an optical fiber.

### Solution to Problem

In order to achieve the above object, a laser processing device according to the present disclosure includes: a laser oscillator that generates a laser light beam; an optical fiber that transmits the laser light beam; a laser head that receives the laser light beam transmitted through the optical fiber and emits the laser light beam to a workpiece; and a chiller that allows cooling water to flow through the laser oscillator to cool the laser oscillator, wherein the laser oscillator includes one or more laser diodes, and a base that includes a cooling water channel inside and has the one or more laser diodes mounted on a surface of the base, and the laser processing device is configured to change an incident angle of the laser light beam incident on the optical fiber by changing a water pressure of the cooling water circulating through the cooling water channel.

### Advantageous Effect of Invention

According to the present disclosure, the beam profile of the laser light beam applied to the workpiece is changed by changing the water pressure of the cooling water, whereby appropriate laser machining can be performed on the workpiece.

### BRIEF DESCRIPTION OF THE DRAWINGS

FIG. 1 is a schematic configuration diagram of a laser processing device according to an exemplary embodiment of the present disclosure.

FIG. 2A is a schematic cross-sectional view of an optical fiber.

FIG. 2B shows a cross-sectional view taken along line IIB-IIB in FIG. 2A and a diagram illustrating a refractive index distribution inside the optical fiber.

FIG. 3 is a schematic configuration diagram of a laser oscillator.

FIG. 4 is a diagram for describing an optical path of a laser light beam when water pressure P of cooling water is P₀.

FIG. 5 is a diagram for describing an optical path of a laser light beam when water pressure P of cooling water is P₁.

FIG. 6 is a diagram for describing an optical path of a laser light beam when water pressure P of cooling water is P₂.

FIG. 7 is a diagram illustrating a relationship between a water pressure of cooling water and a numerical aperture of a laser light beam incident on the optical fiber.

### DESCRIPTION OF EMBODIMENT

An exemplary embodiment of the present disclosure will be described below with reference to the drawings. The following description of preferable exemplary embodiments is merely examples in nature, and is not intended to limit the present disclosure, or application or use of the present disclosure.

### Exemplary Embodiment

### Configuration of Laser Processing Device

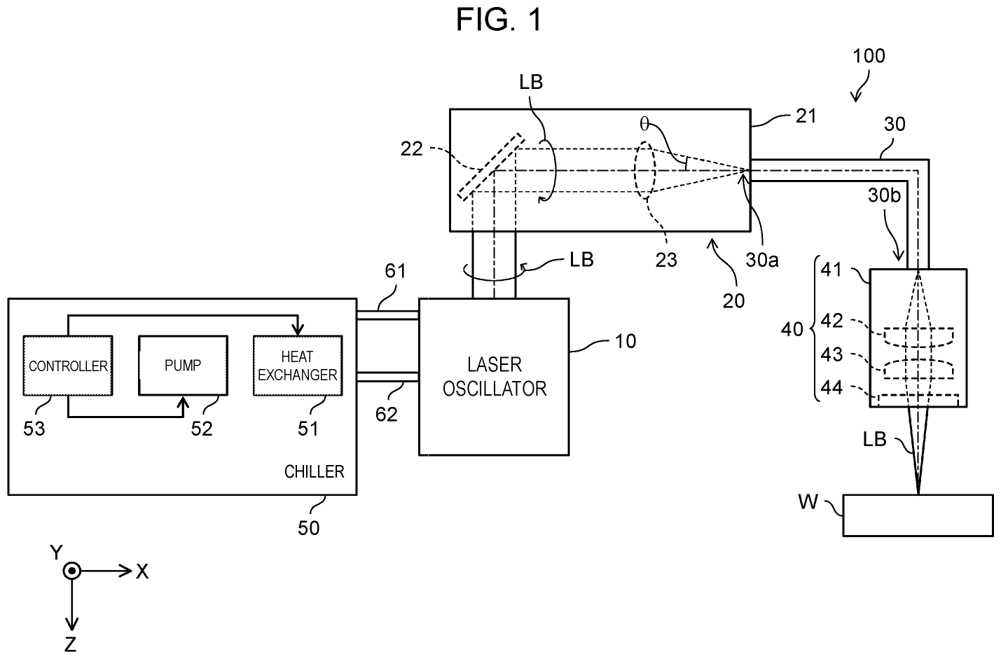

FIG. 1 is a schematic configuration diagram of a laser processing device according to the present exemplary embodiment. Note that, in the following description, a direction perpendicular to incident end surface 30a of optical fiber 30 may be referred to as an X-direction, a direction from laser head 40 toward workpiece W may be referred to as a Z-direction, and a direction orthogonal to the X-direction and the Z-direction may be referred to as a Y-direction.

As illustrated in FIG. 1, laser processing device 100 includes at least laser oscillator 10, condensing optical unit 20, optical fiber 30, laser head 40, and chiller 50. Note that laser processing device 100 includes a power source for driving laser oscillator 10, a control device thereof, and the like, but for convenience of description, they are not illustrated and the description thereof is omitted.

Laser oscillator 10 is a semiconductor laser light source (Direct Diode Laser (DDL)) directly using light emitted from a semiconductor laser, and emits laser light beam LB. In the present exemplary embodiment, the wavelength of laser light beam LB is about 950 nm to 1000 nm. However, the wavelength is not particularly limited thereto, and may have another value. A configuration of laser oscillator 10 will be described in detail later.

Condensing optical unit 20 includes at least first housing 21, reflection mirror 22, and first condenser lens (condenser lens) 23. Reflection mirror 22 and first condenser lens 23 are fixedly placed inside first housing 21 while maintaining a predetermined arrangement relationship with each other. In addition, first housing 21 has a light entrance port (not illustrated) on which laser light beam LB emitted from laser oscillator 10 is incident, and a connector portion (not illustrated) to which optical fiber 30 is connected.

Reflection mirror 22 reflects laser light beam LB entering the inside of first housing 21 toward first condenser lens 23. First condenser lens 23 condenses laser light beam LB reflected by reflection mirror 22 so as to allow laser light beam LB to enter incident end surface 30a of optical fiber 30.

As illustrated in FIG. 1, an angle between an optical axis of laser light beam LB and an outermost side of laser light beam LB in an optical path of laser light beam LB directed to incident end surface 30a of optical fiber 30 from first condenser lens 23 is defined as divergence angle θ.

In this case, the numerical aperture (NA) of laser light beam LB is defined by Expression (1) below.

NA=sin θ (1)

Note that the numerical aperture (NA) is normally maintained also in laser light beam LB emitted from optical fiber 30. That is, in laser light beam LB emitted from optical fiber 30, the relationship represented by Expression (1) is also established.

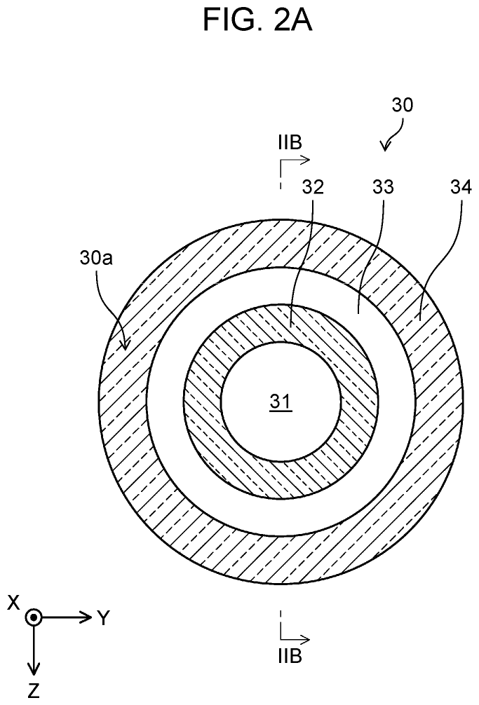

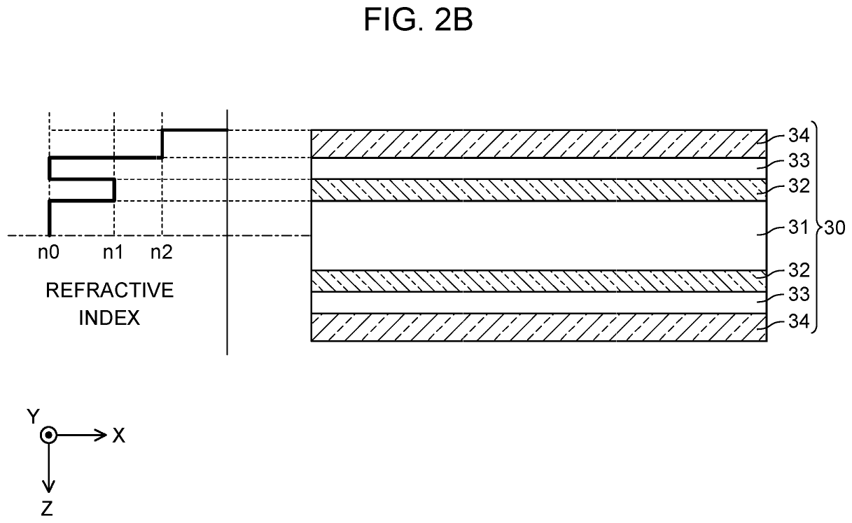

In the present exemplary embodiment, an initial arrangement relationship between reflection mirror 22 and first condenser lens 23 is set so that laser light beam LB enters first core 31 (see FIGS. 2A and 2B) of optical fiber 30. However, as will be described later, laser light beam LB may be incident on first cladding 32 or second core 33 (see FIGS. 2A and 2B) of optical fiber 30.

Optical fiber 30 receives laser light beam LB condensed by first condenser lens 23 of condensing optical unit 20 and transmits laser light beam LB toward laser head 40. The configuration of optical fiber 30 will be described in detail later.

Laser head 40 is configured to receive laser light beam LB transmitted through optical fiber 30 and emit laser light beam LB to workpiece W, and includes at least second housing 41 and a plurality of optical components which are collimation lens 42, second condenser lens 43, and protective glass 44 in the example illustrated in FIG. 1.

Second housing 41 has a connector portion (not illustrated) to which optical fiber 30 is connected, and a light exit port (not illustrated) through which laser light beam LB is emitted toward workpiece W. Further, the plurality of optical components described above is accommodated in second housing 41 while maintaining a predetermined arrangement relationship with each other.

Laser light beam LB incident on the inside of second housing 41 from exit end surface 30b of optical fiber 30 is incident on collimation lens 42 and second condenser lens 43 which are a condensing optical system.

Collimation lens 42 is configured to convert laser light beam LB into collimated light, and second condenser lens 43 is configured to condense laser light beam LB transmitted through collimation lens 42 on or near the surface of workpiece W.

Protective glass 44 is provided to prevent fumes and spatters generated by melting of workpiece W due to irradiation with laser light beam LB from adhering to the optical components inside second housing 41.

Chiller 50 is provided to cool laser oscillator 10 by passing cooling water through laser oscillator 10, and includes at least heat exchanger 51, pump 52, and controller 53.

Heat exchanger 51 adjusts the temperature of the cooling water flowing through cooling water pipes 61 and 62. Heat exchanger 51 has a known configuration, and includes, for example, a tank (not illustrated), a pipe (not illustrated), and a compressor (not illustrated). The pipe is wound around the outer peripheral surfaces of cooling water pipes 61 and 62. A refrigerant stored in the tank is vaporized by the compressor and circulates and flows in the pipe, whereby cooling water pipes 61 and 62 and the cooling water flowing therethrough are cooled by heat of vaporization of the refrigerant. In addition, controller 53 receives a signal from a temperature sensor (not shown) provided in cooling water pipes 61 and 62, and the operation of the compressor is controlled based on this signal, whereby the temperature of the cooling water is maintained within a certain range. It is to be noted that the configuration of heat exchanger 51 is not particularly limited thereto, and other configurations can be applied as appropriate.

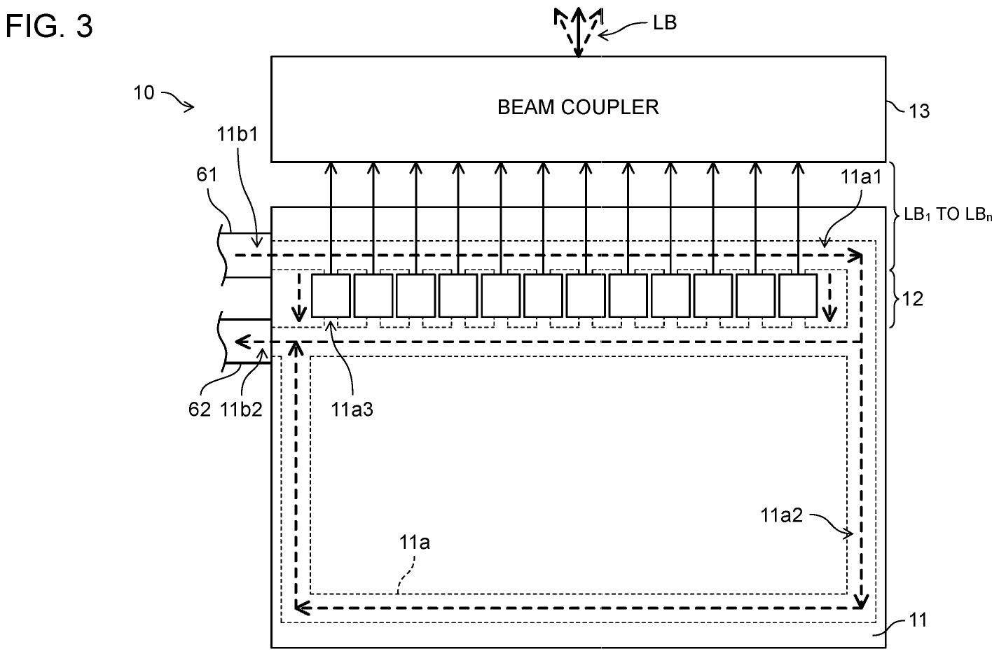

Pump 52 is configured to circulate and pass cooling water to cooling water channel 11a (see FIG. 3) provided in laser oscillator 10 via cooling water pipes 61 and 62. A flow rate of the cooling water discharged from pump 52 is controlled by controller 53.

As described above, controller 53 controls the operations of heat exchanger 51 and pump 52. Note that, when heat exchanger 51 can be operated without special control, controller 53 controls at least the operation of pump 52. Controller 53 includes a microcomputer, an LSI, or the like.

Cooling water pipes 61 and 62 are configured to connect laser oscillator 10 and chiller 50 so that the cooling water flows therein. Cooling water pipes 61 and 62 are integrated, and are configured so that the cooling water flows and circulates through cooling water channel 11a (see FIG. 3) provided in laser oscillator 10. That is, cooling water pipes 61 and 62 and cooling water channel 11a form a closed loop flow path.

Cooling water pipe 61 is connected to a discharge port (not illustrated) of pump 52, and is located on an inlet side of laser oscillator 10. Cooling water pipe 62 is connected to a suction port (not illustrated) of pump 52, and is located on an outlet side of laser oscillator 10. It is to be noted, however, that cooling water pipe 61 and cooling water pipe 62 may be switched.

Note that laser processing device 100 may be provided with a manipulator (not illustrated) that retains laser head 40. The manipulator which is, for example, an articulated robot is connected to a control device (not illustrated) and moves laser head 40 to a desired position at a desired speed on the basis of an operation command from the control device. With this configuration, laser light beam LB emitted from laser head 40 is applied to the surface of workpiece W so as to draw a desired trajectory.

### Configuration of Optical Fiber

FIG. 2A shows a schematic cross-sectional view of the optical fiber, and FIG. 2B shows a cross-sectional view taken along line IIB-IIB in FIG. 2A and a refractive index distribution inside the optical fiber. Note that FIGS. 2A and 2B are merely schematic, and the dimensions of components in FIGS. 2A and 2B are different from actual dimensions of the components of optical fiber 30.

As illustrated in FIGS. 2A and 2B, optical fiber 30 includes at least: first core 31 and second core 33, each of which is an optical waveguide; first cladding 32; and second cladding 34. An outer peripheral surface of second cladding 34 is covered with a light shielding coating (not illustrated).

First core 31 has a circular shape in cross section, and is disposed at the center of the axis of optical fiber 30. First cladding 32 is disposed coaxially with first core 31 in contact with the outer peripheral surface of first core 31, and has a ring shape in cross section. Second core 33 is disposed coaxially with first core 31 in contact with the outer peripheral surface of first cladding 32, and has a ring shape in cross section. Second cladding 34 is disposed coaxially with first core 31 in contact with the outer peripheral surface of second core 33, and has a ring shape in cross section.

First core 31, second core 33, first cladding 32, and second cladding 34 are all made of quartz. However, refractive index n₁ of first cladding 32 is set to be lower than refractive index n₀ of first core 31. Note that refractive index no of second core 33 is set to be the same as refractive index n₀ of first core 31. Refractive index n₂ of second cladding 34 is set to be lower than refractive index n₁ of first cladding 32.

With the configuration of optical fiber 30 as described above, when laser light beam LB is incident on first cladding 32, laser light beam LB is propagated mainly to first core 31 and second core 33. The ratio of laser light beam LB propagated to first core 31 and second core 33 depends on the distances between the incident position of laser light beam LB and first and second cores 31 and 33. A part of laser light beam LB is also propagated to first cladding 32.

On the other hand, when laser light beam LB propagates through second core 33, laser light beam LB hardly enters the inside of second cladding 34. That is, laser light beam LB propagates through the inside of second core 33 and reaches laser head 40.

### Configuration of Laser Oscillator

FIG. 3 is a schematic configuration diagram of the laser oscillator. Laser oscillator 10 includes at least base 11, a plurality of laser diodes 12, and beam coupler 13 inside a housing not illustrated. In the following description, the thickness direction of base 11 may be referred to as a vertical direction. In the vertical direction, a side of base 11 on which laser diodes 12 are mounted may be referred to by the term “top”, “upward”, or “upper side”, and the opposite side may be referred to by the term “bottom”, “downward”, or “lower side”.

Base 11 is a rectangular parallelepiped component having cooling water channel 11a formed therein. Base 11 is made of a metal having high thermal conductivity such as copper, and is coated with a coating (not illustrated) such as gold on the surface as necessary.

Cooling water channel 11a includes first water channel 11a1, second water channel 11a2, and a plurality of third water channels 11a3. A broken line arrow illustrated in FIG. 3 indicates a direction of flow of the cooling water.

First water channel 11a1 extends along the array direction of the plurality of laser diodes 12 from inlet 11b1 to which cooling water pipe 61 is connected. This portion of first water channel 11a1 is disposed near light emission points of the plurality of laser diodes 12. First water channel 11a1 is turned back around the plurality of laser diodes 12 in plan view, extends along the array direction of the plurality of laser diodes 12, and reaches outlet 11b2 to which cooling water pipe 62 is connected.

Second water channel 11a2 branches from the turned-back portion of first water channel 11a1, extends along the outer periphery of base 11, and reaches outlet 11b2. Each of third water channels 11a3 extends so as to connect two portions extending in parallel in first water channel 11a1. Each of third water channels 11a3 is provided below corresponding one of the plurality of laser diodes 12.

Each of the plurality of laser diodes 12 is mounted on the surface of base 11 via an adhesive (not illustrated). Laser diodes 12 may be mounted directly on the surface of base 11. Furthermore, laser diodes 12 may be mounted on the surface of base 11 via a submount (not illustrated) or the like. The plurality of laser diodes 12 is arranged at intervals along the longitudinal direction of first water channel 11a1. In the present exemplary embodiment, the number of laser diodes 12 is eleven, but is not particularly limited thereto.

When the cooling water is supplied from inlet 11b1 to cooling water channel 11a, the cooling water flows to outlet 11b through first water channel 11a1. At this time, the cooling water supplied from chiller 50 via cooling water pipe 61, that is, the cooling water having a constant temperature, directly flows into first water channel 11a. Thus, it is possible to improve the cooling efficiency of portions near the light emission points in the plurality of laser diodes 12, whereby the temperature rise of laser diodes 12 can be suppressed.

In addition, since the cooling water flows through third cooling water channels 11a3 respectively provided below the plurality of laser diodes 12, the cooling efficiency of laser diodes 12 is further improved, and the temperature rise of laser diodes 12 can be suppressed.

The cooling water flows through first water channel 11a1, and at the same time, flows from the branch portion of first water channel 11a1 to outlet 11b through second water channel 11a2. This can cool base 11 entirely, so that the temperature of base 11 is stabilized. Thus, the temperature rise of laser diodes 12 can be suppressed.

Beam coupler 13 receives laser light beams LB₁ to LBₙ emitted from the plurality of laser diodes 12, and couples laser light beams LB₁ to LBₙ into one laser light beam LB. The space coupling may be used for coupling the laser light beams. In addition, when the wavelengths of laser light beams LB₁ to LBₙ are different from each other, the wavelengths of laser light beams LB₁ to LBₙ may be coupled to form one laser light beam LB. The type and number of the optical components provided in beam coupler 13 and the arrangement relationship therebetween can be appropriately changed according to the coupling method.

Note that, when only one laser diode 12 is mounted on base 11, beam coupler 13 is omitted.

### Knowledge Leading to Present Invention

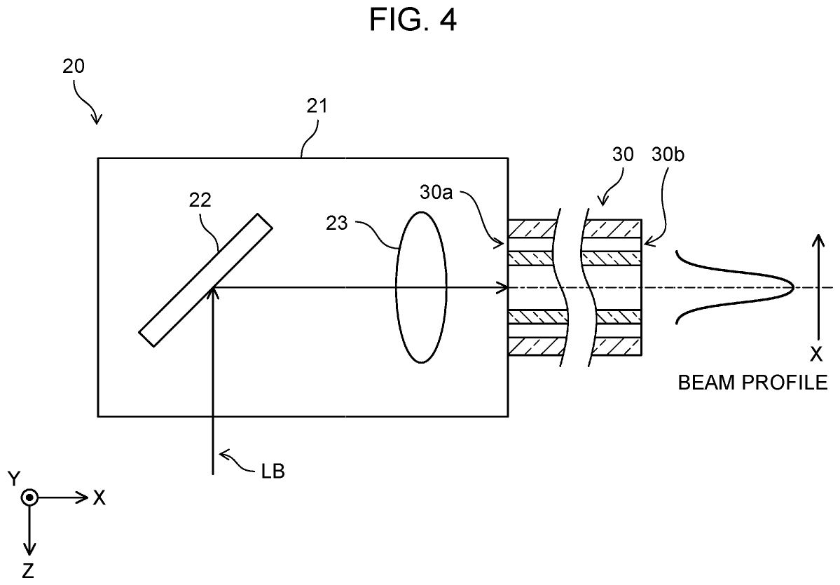

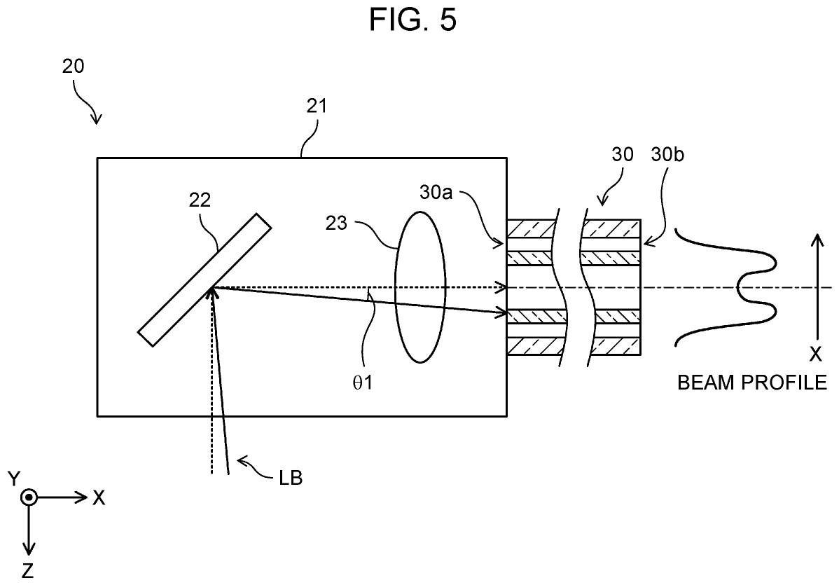

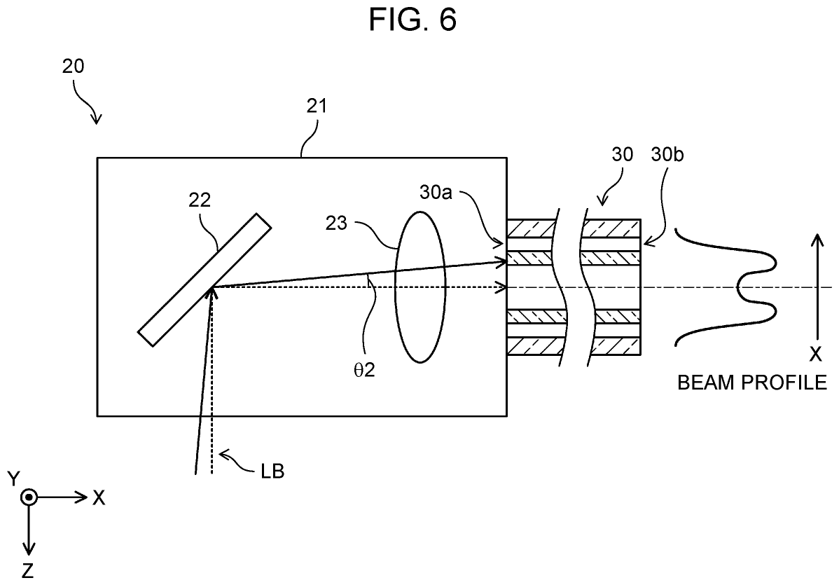

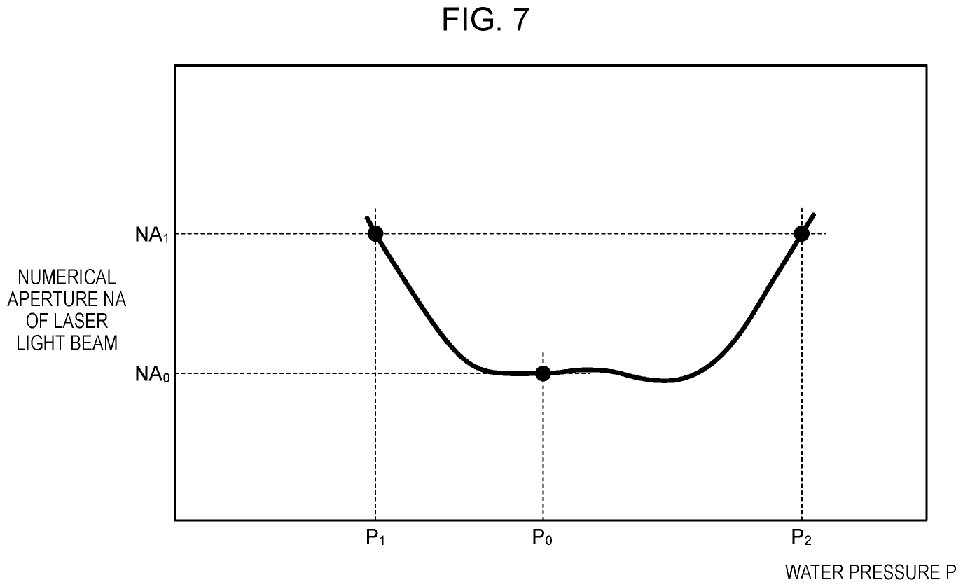

FIG. 4 is an explanatory diagram of the optical path of the laser light beam when water pressure P of the cooling water is P₀, FIG. 5 is an explanatory diagram of the optical path of the laser light beam when water pressure P of the cooling water is P₁, and FIG. 6 is an explanatory diagram of the optical path of the laser light beam when water pressure P of the cooling water is P₂. FIG. 7 shows the relationship between the water pressure of the cooling water and a numerical aperture of the laser light beam incident on the optical fiber. Note that, for convenience of description, FIGS. 4 to 6 illustrate only the optical axis of laser light beam LB. In addition, a one-dimensional distribution of the power density in the X-direction is illustrated as a beam profile of laser light beam LB. In FIGS. 4 to 6, the X-direction is illustrated as a direction parallel to the surface of workpiece W.

As illustrated in FIG. 4, when water pressure P of the cooling water is P₀, laser light beam LB entering condensing optical unit 20 enters reflection mirror 22. Reflection mirror 22 is disposed so that the angle between the surface thereof and the optical axis of laser light beam LB is 45 degrees. Therefore, laser light beam LB reflected by reflection mirror 22 is incident on first condenser lens 23 at an angle of 90 degrees with respect to the original optical axis. At this time, first condenser lens 23 and optical fiber 30 are disposed in advance such that the optical axis of laser light beam LB, the center of first condenser lens 23, and first core 31 of optical fiber 30 are located substantially on a straight line. Therefore, laser light beam LB is incident substantially perpendicularly to incident end surface 30a of optical fiber 30, and laser light beam LB propagates through the inside of first core 31 and reaches laser head 40.

On the other hand, the inventors of the present application have found that the numerical aperture of laser light beam LB incident on optical fiber 30 changes when water pressure P of the cooling water is changed.

As illustrated in FIG. 7, when water pressure P of the cooling water is within a predetermined range (sometimes referred to as a normal use range hereinafter) including P₀, the numerical aperture of laser light beam LB hardly changes. On the other hand, when water pressure P of the cooling water is lower than the predetermined range, the numerical aperture of laser light beam LB increases with a decrease in water pressure P. In addition, when water pressure P of the cooling water is higher than the normal use range, the numerical aperture of laser light beam LB increases with an increase in water pressure P.

This phenomenon is considered to occur because base 11 is slightly deformed near cooling water channel 11a, particularly first water channel 11a1 into which the cooling water first flows, due to the change in water pressure P of the cooling water. That is, when water pressure P of the cooling water is lower than the normal use range, the pressure balance greatly changes between the inside and the outside of cooling water channel 11a, and thus, base 11 is slightly deformed. As a result, the optical axes of laser light beams LB₁ to LBₙ emitted from laser diodes 12 are directed downward with respect to the original direction. In addition, when water pressure P of the cooling water is higher than the normal use range, the pressure balance greatly changes between the inside and the outside of cooling water channel 11a, and thus, base 11 is slightly deformed. As a result, the optical axes of laser light beams LB₁ to LBₙ emitted from laser diodes 12 are directed upward with respect to the original direction.

The change of direction of the optical axes of laser light beams LB₁ to LBₙ changes the direction of the optical axis of laser light beam LB formed by coupling laser light beams LB₁ to LBₙ. As a result, when water pressure P of the cooling water is P₁ lower than P₀, laser light beam LB enters condensing optical unit 20 while inclining at angle θ1 from the original optical axis as illustrated in FIG. 5, for example. Thus, the incident angle of laser light beam LB incident on incident end surface 30a of optical fiber 30 is also inclined at angle θ1 from the original angle. The inclination of the optical axis is reflected on the numerical aperture of laser light beam LB, and in the example illustrated in FIG. 5, the numerical aperture of laser light beam LB is expressed by the relationship represented by Expression (2).

NA₁=sin(θ+θ1) (2)

Here, if 0°<θ<90° and 0°<θ+θ1<90° are satisfied, the relationship of Expression (3) is established.

NA₁>sin θ(=NA₀) (3)

Further, when water pressure P of the cooling water is P₂ higher than P₀, laser light beam LB enters condensing optical unit 20 while inclining at angle θ2 from the original optical axis. Thus, the incident angle of laser light beam LB incident on incident end surface 30a of optical fiber 30 is also inclined at angle θ2 from the original angle. The inclination of the optical axis is reflected on the numerical aperture of laser light beam LB. Here, when 0°<↓<90°, 0°<θ+θ2<90°, and θ1=θ2 are satisfied, the numerical aperture of laser light beam LB is expressed by the relationships represented by Expressions (4) and (5) in the example illustrated in FIG. 6.

NA₁=sin(θ+θ2)(=sin(θ+θ1)) (4)

NA₁>sin θ(=NA₀) (5)

In addition, as illustrated in FIGS. 5 and 6, when the incident angle of laser light beam LB incident on incident end surface 30a of optical fiber 30 is inclined at about angle θ1 or angle θ2 from the original angle, laser light beam LB is incident on first cladding 32. As described above, laser light beam LB incident on first cladding 32 is split and transmitted to first core 31 and second core 33.

As a result, the beam profile of laser light beam LB emitted from optical fiber 30 has a unimodal Gaussian distribution in the example illustrated in FIG. 4, whereas in the examples illustrated in FIGS. 5 and 6, the beam profile has a bimodal distribution.

### Effects and Others

As described above, laser processing device 100 according to the present exemplary embodiment includes laser oscillator 10 that emits laser light beam LB, and optical fiber 30 that transmits laser light beam LB. Laser processing device 100 also includes at least laser head 40 that receives laser light beam LB transmitted through optical fiber 30 and emits received laser light beam LB to workpiece W, and chiller 50 that supplies cooling water to laser oscillator 10 for cooling.

Laser oscillator 10 includes at least a plurality of laser diodes 12 and base 11 having cooling water channel 11a therein and having laser diodes 12 mounted on a surface thereof.

Laser processing device 100 is configured to change the incident angle of laser light beam LB entering optical fiber 30 by changing water pressure P of the cooling water circulating through cooling water channel 11a.

In other words, laser processing device 100 is configured to change the numerical aperture (NA) of laser light beam LB emitted from optical fiber 30 by changing water pressure P of the cooling water circulating through cooling water channel 11a.

In addition, optical fiber 30 includes first core 31 at the center of the axis, and first cladding 32 provided coaxially with first core 31 in contact with the outer peripheral surface of first core 31.

Optical fiber 30 also includes at least second core 33 provided coaxially with first core 31 in contact with the outer peripheral surface of first cladding 32, and second cladding 34 provided coaxially with first core 31 in contact with the outer peripheral surface of second core 33.

In laser processing device 100 according to the present exemplary embodiment, when water pressure P of the cooling water is set to pressure P₀ within the normal use range, laser light beam LB propagates through the inside of first core 31 of optical fiber 30 and reaches laser head 40 as illustrated in FIGS. 4 and 7.

On the other hand, due to the above-described configuration, laser processing device 100 according to the present exemplary embodiment changes water pressure P of the cooling water from P₀ to pressure P1 lower than P₀ or to pressure P₂ higher than P₀, so that laser light beam LB propagates through the inside of each of first core 31 and second core 33 and reaches laser head 40.

As a result, the beam profile of laser light beam LB emitted from optical fiber 30 can be changed from a unimodal Gaussian distribution to a bimodal distribution.

That is, laser processing device 100 according to the present exemplary embodiment is configured to change the beam profile of laser light beam LB emitted from optical fiber 30 by changing water pressure P of the cooling water circulating through cooling water channel 11a.

For example, a case of cutting workpiece W made of mild steel using a laser is considered. When workpiece W is, for example, a thin plate having a thickness of about 1 mm to 3 mm, the beam profile of laser light beam LB emitted from optical fiber 30 and applied to workpiece W is set to a unimodal Gaussian distribution as illustrated in FIG. 4. That is, laser processing device 100 is designed in such a manner that laser light beam LB is incident substantially perpendicularly to incident end surface 30a of optical fiber 30, and laser light beam LB propagates through the inside of first core 31 and reaches laser head 40. In this way, the cutting width of workpiece W can be reduced, and the cut surface can be smoothed.

On the other hand, when workpiece W is a thick plate having a thickness of, for example, about 15 mm to 25 mm, the beam profile illustrated in FIG. 4 provides a narrow heat input range to workpiece W, and therefore, desired cutting may not be performed. In such a case, water pressure P of the cooling water is lowered from P₀ to P₁ so that the beam profile of laser light beam LB emitted from optical fiber 30 and applied to workpiece W has a bimodal distribution as illustrated in FIG. 5. In this way, the heat input can be ensured with respect to the cut portion of workpiece W, and the cut surface can be smoothed.

As described above, according to the present exemplary embodiment, the beam profile of laser light beam LB applied to workpiece W is changed by changing water pressure P of the cooling water according to the shape or the like of workpiece W, whereby appropriate laser machining can be performed on workpiece W.

Note that, when the incident angle of laser light beam LB incident on optical fiber 30 and the beam profile of laser light beam LB applied to workpiece W are changed, it is preferable to change water pressure P of the cooling water to pressure P₁ lower than pressure P₀ in the normal use range. This configuration can prevent an application of an excessive load to base 11. However, if base 11 is sufficiently rigid, water pressure P of the cooling water may be changed to pressure P₂ higher than pressure P₀ in the normal use range. In addition, it is obvious that pressure P₁ or pressure P₂ is changed according to the incident angle of laser light beam LB entering optical fiber 30.

In the present exemplary embodiment, when water pressure P of the cooling water is set to pressure P₀ within the normal operating pressure, laser light beam LB propagates through the inside of first core 31 of optical fiber 30. However, laser light beam LB may propagate through the inside of first core 31 and second core 33 under this pressure condition. In this case, water pressure P of the cooling water may be changed from pressure P₀ so that laser light beam LB is transmitted to first core 31 of optical fiber 30, and the beam profile of laser light beam LB applied to workpiece W has a unimodal Gaussian distribution.

Chiller 50 includes at least heat exchanger 51 that adjusts the temperature of the cooling water, pump 52 that passes and circulates the cooling water through cooling water channel 11a, and controller 53 that controls at least the operation of pump 52. Controller 53 is configured to change the water pressure of the cooling water flowing through cooling water channel 11a by changing a flow rate of the cooling water discharged from pump 52.

With this configuration, the water pressure of the cooling water flowing through cooling water channel 11a can be easily changed by using chiller 50 having a known configuration. In addition, it is considered that, in laser processing device 100 including high-output laser oscillator 10, it is necessary to provide chiller 50 that cools laser oscillator 10. That is, it is possible to change the incident angle of laser light beam LB entering optical fiber 30 without adding special equipment in configuring laser processing device 100 that is commonly used. As a result, the beam profile of laser light beam LB applied to workpiece W is changed, and appropriate laser machining can be performed on workpiece W.

In addition, laser processing device 100 further includes condensing optical unit 20 having at least reflection mirror 22 and first condenser lens (condenser lens) 23.

Reflection mirror 22 reflects laser light beam LB emitted from laser oscillator 10 toward first condenser lens 23, and first condenser lens 23 condenses laser light beam LB and allows laser light beam LB to be incident on incident end surface 30a of optical fiber 30.

Laser processing device 100 is further configured to change the incident angle of laser light beam LB entering reflection mirror 22 by changing the water pressure of the cooling water circulating through cooling water channel 11a.

With this configuration, the incident angle of laser light beam LB entering incident end surface 30a of optical fiber 30 can be easily changed. In addition, the beam profile of laser light beam LB applied to workpiece W is changed, and appropriate laser machining can be performed on workpiece W.

### Other Exemplary Embodiments

In the above-described exemplary embodiment, optical fiber 30 has a so-called double core structure. However, a fiber having a single core structure may be used. In this case, the incident angle of laser light beam LB entering incident end surface 30a of optical fiber 30 can also be changed by changing water pressure P of the cooling water. Thus, the numerical aperture of laser light beam LB can be increased, for example. In this case, the beam profile of laser light beam LB applied to workpiece W is maintained to have a unimodal shape as illustrated in FIG. 4, but the half width increases, and thus, the beam profile is wider.

Furthermore, in the present specification, laser cutting has been described as an example, but it is obvious that laser processing device 100 according to the present disclosure can be applied to other kinds of processing, for example, laser welding, laser drilling, and the like.

### INDUSTRIAL APPLICABILITY

The laser processing device according to the present disclosure can change the incident position of a laser light beam on the incident end surface of the optical fiber and adjust the beam profile of the laser light beam with a simple configuration, and thus is useful as a laser processing device capable of performing various kinds of laser processing.

### REFERENCE MARKS IN THE DRAWINGS

10: laser oscillator

11: base

11a: cooling water channel

12: laser diode

13: beam coupler

20: condensing optical unit

21: first housing

22: reflection mirror

23: first condenser lens (condenser lens)

30: optical fiber

30a: incident end surface

30b: exit end surface

31: first core

32: first cladding

33: second core

34: second cladding

40: laser head

41: second housing

42: collimation lens

43: second condenser lens

44: protective glass

50: chiller

51: heat exchanger

52: pump

53: controller

61, 62: cooling water pipe

100: laser processing device

1. A laser processing device comprising:
a laser oscillator that generates a laser light beam;
an optical fiber that transmits the laser light beam;
a laser head that receives the laser light beam transmitted through the optical fiber and emits the laser light beam to a workpiece; and
a chiller that allows cooling water to flow through the laser oscillator to cool the laser oscillator,
wherein
the laser oscillator includes
one or more laser diodes, and
a base that includes a cooling water channel inside and has the one or more laser diodes mounted on a surface of the base, and
the laser processing device is configured to change an incident angle of the laser light beam incident on the optical fiber by changing a water pressure of the cooling water circulating through the cooling water channel.

2. The laser processing device according to claim 1, wherein
the chiller includes:
a heat exchanger that adjusts a temperature of the cooling water;
a pump that passes and circulates the cooling water through the cooling water channel; and
a controller that controls at least an operation of the pump,
the controller being configured to change the water pressure of the cooling water flowing through the cooling water channel by changing a flow rate of the cooling water discharged from the pump.

3. The laser processing device according to claim 1, further comprising a condensing optical unit that includes a reflection mirror and a condenser lens,
wherein
the reflection mirror reflects the laser light beam emitted from the laser oscillator toward the condenser lens,
the condenser lens condenses the laser light beam and allows the laser light beam to be incident on an incident end surface of the optical fiber, and
the laser processing device is configured to change an incident angle of the laser light beam incident on the reflection mirror by changing the water pressure of the cooling water circulating through the cooling water channel.

4. The laser processing device according to claim 1, wherein the optical fiber includes:
a first core at a center of an axis;
a first cladding provided coaxially with the first core in contact with an outer peripheral surface of the first core;
a second core provided coaxially with the first core in contact with an outer peripheral surface of the first cladding; and
a second cladding provided coaxially with the first core in contact with an outer peripheral surface of the second core.

5. The laser processing device according to claim 4, wherein the laser processing device is configured to transmit the laser light beam to the first core and the second core by changing the water pressure of the cooling water circulating through the cooling water channel.

6. The laser processing device according to claim 4, wherein the laser processing device is configured to transmit the laser light beam to the first core by changing the water pressure of the cooling water circulating through the cooling water channel.

7. The laser processing device according to claim 1, wherein the laser processing device is configured to change a beam profile of the laser light beam emitted from the optical fiber by changing the water pressure of the cooling water circulating through the cooling water channel.
